(19) United States
(12) Patent Application Publication
(10) Pub. No.: US 2015/0136939 A1
(43) Pub. Date: May 21, 2015

(54) SUPPORT SYSTEM

(71) Applicant: Stuart Haselden, Wellington (NZ)

(72) Inventor: Stuart Haselden, Wellington (NZ)

(21) Appl. No.: 14/404,139

(22) PCT Filed: May 30, 2012
(86) PCT No.: PCT/NZ2012/000077

§ 371 Date: Jan. 7, 2015

(51) Int. Cl. F16F 1/16; E04H 9/02; H05K 7/14; F16F 1/14; F16F 15/02

(52) U.S. Cl. CPC F16F 1/16; F16F 1/14; F16F 15/02; H05K 7/1485; E04H 9/02
USPC 248/608; 248/560

(57) ABSTRACT

A support system (1) for substantially isolating an object (100) from abrupt movement of a foundation. The support system (1) has a frame (3) operatively attached to the foundation and a cradle (11) for supporting the object (100). The support system also has a horizontal isolation component (5) and a vertical isolation component (7). The horizontal isolation component (5) is configured to allow movement of the frame (3) relative to the foundation and dampen movement of the object (100) in a horizontal direction during abrupt movement of the foundation. The vertical isolation component is operatively connected between the frame (3) and the cradle (11). The vertical isolation component is configured to allow movement of the cradle (11) relative to the frame (3) in a vertical direction and dampen movement of the object (100) in a vertical direction during abrupt movement of the foundation.

### TECHNICAL FIELD

The present invention provides a support system for substantially isolating an item from an abrupt event. The item may be a container and the abrupt event may be a seismic event. It should be apparent to those skilled in the art that the system can also be used to protect other components and/or instruments from vibrations or abrupt forces.

### BACKGROUND

Many instruments, computers and other equipment these days can be classified as fragile or very fragile. Although technically this equipment may be moved, it must be done with care, as large forces (such as dropping, banging, knocking, or shaking, potentially by seismic events such as earthquakes) can irrevocably harm the internal components, meaning the instrument or computer no longer works. Such delicate instruments that may be affected by seismic events include magnetic instruments, components with delicate calibrations and measurement instruments.

To accommodate all the data that is transferred and stored by computers, in the last 10-15 years, huge data centres have been built. These centres house large banks of computers and are designed to store as many computers as possible, while carefully maintaining conditions that optimise the efficiency of the computers. The environment is usually cooled and air flow through the centre monitored to ensure the computers do no overheat.

Recently, many companies have moved their data centres into modified containers from dedicated floors in buildings. Some of these containers may be modified shipping containers, which have traditionally been used to move freight across the ocean. However, a growing number of manufacturers are manufacturing purpose built dedicated containers/portable data centres. A number of major companies (mainly IT) manufacture these portable data centres; essentially a data centre in a box, The data centres have their own cooling and power supply. The advantages of this are:
reduced power consumption (up to 50% claimed)
portable (easy and quick to ship and install)
lower capital costs (compared to a building project)

Further advantages of putting data centres in these portable units include easy expansion, the confined construction means that cooling can be more efficient, and then there is the fact that the containers can be placed in areas that have cheaper warehouses and/or in places with cheap power. A containerised data centre can be moved to new locations and connected relatively easily.

These products are sold as being ideal for companies running out of space in current data centres, as well as part of disaster recovery and for remote IT set-up. However, the movement of data centres out of specialised buildings means that containerised data centres are particularly vulnerable to seismic events. There has also been a recognition that the upper floors of buildings experience significant higher levels of acceleration during seismic shaking. When stored in a basic warehouse, or even outside, the containerised data centre is a simple building, and may not be subject to more stringent building standards that exist in most first world countries. Data centres need to protect against damage from fire, flooding, vandalism, power outage, vibration and earthquake. Most of these are easily dealt with, except for earthquake.

During an earthquake vertical acceleration can be as high as horizontal acceleration especially near an epicentre. There are few designs for vertical earthquake isolators in structures as vertical acceleration is less of a threat to buildings due to their inherent strength. Vertical acceleration is a threat to data centre contents as excessive vibrations are detrimental to disk drives and servers.

Sensitive components such as data centres, fragile equipment, artworks, or other delicate items need to be protected against damage from fire, flooding, vandalism, power outage, vibration and earthquake. Most of these are easily dealt with except for earthquake. Some existing portable solutions use isolators which protect from horizontal movement associated with earthquakes. However, we are not aware of any existing product that provides isolation (and hence protection) from both the horizontal and vertical movement at a level that would be involved in a major earthquake. Although horizontal isolation components are known for buildings, the combination of horizontal isolation, vertical isolation in a support system for pre-existing modular enclosures was previously unknown.

It would be an advantage to have some way of protecting things sensitive to vibrations from seismic events or other vibration causing events. It would be preferable to be able to protect other vibration sensitive equipment, such as instruments, magnetic devices and other fragile equipment and even smaller structures like buildings in certain applications, from large abrupt forces.

It is therefore an object of the present invention to provide a system which offers an improvement over current isolating technologies, and/or at least to provide the public with a useful choice.

In this specification where reference has been made to patent specifications, other external documents, or other sources of information, this is generally for the purpose of providing a context for discussing the features of the invention. Unless specifically stated otherwise, reference to such external documents is not to be construed as an admission that such documents, or such sources of information, in any jurisdiction, are prior art, or form part of the common general knowledge in the art.

### SUMMARY OF THE INVENTION

In accordance with a first aspect of the invention, there is provided a support system for substantially isolating an object from abrupt movement of a foundation, the support system comprising: a horizontal isolation component configured to dampen the movement of the object in a horizontal direction, and a vertical isolation component configured to dampen the movement of the object in a vertical direction, wherein the vertical isolation component is configured to dampen at least +/−150 mm of movement of the object relative to the foundation in the vertical direction.

In one embodiment, the support system further comprises a frame for containing and supporting the object.

In one embodiment, the frame comprises a main frame, and a cradle for containing and supporting the object, and wherein the vertical isolation component dampens the cradle and object from movement of the main frame and foundation in a vertical direction.

In one embodiment, the support system comprises three or more vertical isolation components.

In an embodiment, the vertical isolation component is configured to substantially isolate the object from vertical movement of the foundation of at least +/−300 mm of movement of the foundation in the vertical direction.

A support system according to any one of the preceding claims, wherein the vertical isolation component comprises at least one suspension element.

In one embodiment, the suspension element comprises a torsion bar.

In one embodiment, the suspension element comprises a pair of arms, the arms being pivotally connected to each other at one end of each arm and fixed to the torsion bar at the other end of each arm.

In one embodiment, the suspension element comprises a first pair of arms, a respective first pair of torsion bars, a second pair of arms, and a respective second pair of torsion bars, each of the arms of the first pair of arms being pivotally connected to each other at one end and fixed to a respective torsion bar of the first pair of torsion bars at the other end, each of the arms of the second pair of arms being pivotally connected to each other at one end and fixed to a respective torsion bar of the second pair of torsion bars at the other end, and wherein the first pair of arms, the respective first pair of torsion bars, the second pair of arms, and the respective second pair of torsion bars are arranged to dampen movement of the object in a vertical direction during abrupt movement of the foundation.

In one embodiment, the horizontal isolation component comprises a base isolation element for isolating the main frame, cradle and object from movement of the foundation in a horizontal direction.

In one embodiment, the support system comprises three or more horizontal isolation components.

In one embodiment, the horizontal isolation component(s) are/is fixed to the ground, floor, or other foundation element.

In one embodiment, the horizontal isolation component is configured to dampen at least +/−500 mm of movement of the foundation in a horizontal direction.

In one embodiment, the horizontal isolation component and the vertical isolation component dampen substantially the same amount of movement.

In one embodiment, the horizontal isolation component(s) and the vertical isolation component(s) dampen an equivalent amount of movement.

In one embodiment, the component may be an enclosure, which may hold other components, instruments or fragile items.

Abrupt movement may refer to vibrations or seismic activity. Alternatively abrupt movement may refer to external forces acting on the component or support system.

In one embodiment, there are three or more horizontal isolation components.

In one embodiment, the horizontal isolation components are fixed to the ground, floor, or other foundation element.

In one embodiment, the horizontal isolation component may allow horizontal movement by up to +/−500 mm.

In one embodiment, the suspension element is configured to dampen vertical movement of at least 300 mm of displacement.

In one embodiment, the suspension element may allow vertical movement by at least +/−300 mm.

In accordance with a second aspect of the invention, there is provided a combination of a support system as described above in relation to the first aspect together with an object supported by the support system.

In one embodiment, the object comprises an enclosure. In one embodiment, the enclosure comprises a containerised data centre.

In one embodiment, the object comprises a building.

In one embodiment, the modular enclosure is a containerised data centre. Alternatively, the modular enclosure may be any other enclosure, such as that housing sensitive data measurement equipment.

In accordance with a third aspect of the invention, there is provided a support system for substantially isolating an object from abrupt movement of a foundation, the support system comprising:
a frame operatively attached to the foundation;
a cradle for supporting the object;
a horizontal isolation component, the horizontal isolation component being configured to allow movement of the frame relative to the foundation and dampen movement of the object in a horizontal direction during abrupt movement of the foundation; and
a vertical isolation component operatively connected between the frame and the cradle, the vertical isolation component being configured to allow movement of the cradle relative to the frame in a vertical direction and dampen movement of the object in a vertical direction during abrupt movement of the foundation.

In one embodiment, the vertical isolation component is configured to allow and dampen at least 300 mm of movement of the cradle relative to the frame in a vertical direction.

In one embodiment, the support system comprises three or more vertical isolation components.

In one embodiment, the vertical isolation component(s) comprises at least one suspension element.

In one embodiment, the suspension element comprises a torsion bar.

In one embodiment, the suspension element comprises a pair of arms, the arms being pivotally connected to each other at one end of each arm and connected to the torsion bar at the other end of each arm.

In one embodiment, the suspension element comprises a first pair of arms, a respective first pair of torsion bars, a second pair of arms, and a respective second pair of torsion bars, each of the arms of the first pair of arms being pivotally connected to each other at one end and fixed to a respective torsion bar of the first pair of torsion bars at the other end, each of the arms of the second pair of arms being pivotally connected to each other at one end and fixed to a respective torsion bar of the second pair of torsion bars at the other end, and wherein the first pair of arms, the respective first pair of torsion bars, the second pair of arms, and the respective second pair of torsion bars are arranged to dampen movement of the object in a vertical direction during abrupt movement of the foundation.

In one embodiment, the horizontal isolation component comprises a base isolation element for isolating the main frame, cradle and object from movement of the foundation in a horizontal direction.

In one embodiment, the support system comprises three or more horizontal isolation components.

In one embodiment, the horizontal isolation component(s) are/is fixed to the ground, floor, or other foundation element.

In one embodiment, the horizontal isolation component(s) is configured to allow and dampen at least +/−500 mm of movement of the frame relative to the foundation in a horizontal direction.

In one embodiment, the horizontal isolation component(s) and the vertical isolation component(s) dampen substantially the same amount of movement.

In one embodiment, the horizontal isolation component(s) and the vertical isolation component(s) dampen an equivalent amount of movement.

In one embodiment, the horizontal isolation component(s) and the vertical isolation component(s) operate independently of each other.

In accordance with a fourth aspect of the invention, there is provided a combination of a support system as described above in relation to the third aspect together with an object supported by the support system.

In one embodiment, the object comprises an enclosure. In one embodiment, the enclosure comprises a containerised data centre.

The term ‘comprising’ as used in this specification and claims means ‘consisting at least in part of’. When interpreting statements in this specification and claims which include the term ‘comprising’, other features besides the features prefaced by this term in each statement can also be present. Related terms such as ‘comprise’ and ‘comprised’ are to be interpreted in a similar manner.

It is intended that reference to a range of numbers disclosed herein (for example, 1 to 10) also incorporates reference to all rational numbers within that range (for example, 1, 1.1, 2, 3, 3.9, 4, 5, 6, 6.5, 7, 8, 9 and 10) and also any range of rational numbers within that range (for example, 2 to 8, 1.5 to 5.5 and 3.1 to 4.7) and, therefore, all sub-ranges of all ranges expressly disclosed herein are hereby expressly disclosed. These are only examples of what is specifically intended and all possible combinations of numerical values between the lowest value and the highest value enumerated are to be considered to be expressly stated in this application in a similar manner.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting. Where specific integers are mentioned herein which have known equivalents in the art to which this invention relates, such known equivalents are deemed to be incorporated herein as if individually set forth.

As used herein, the term ‘(s)’ following a noun means the plural and/or singular form of that noun.

As used herein, the term ‘and/or’ means ‘and’ or ‘or’, or where the context allows both.

The invention consists in the foregoing and also envisages constructions of which the following gives examples only.

### BRIEF DESCRIPTION OF THE DRAWINGS

The present invention will now be described by way of example only and with reference to the accompanying drawings in which:

FIG. 1 shows an embodiment of the support system;

FIG. 2 shows an expanded view of the isolation components of the support system;

FIG. 3 shows a perspective view of a second embodiment of the support system together with a shipping container;

FIG. 4 shows a perspective view of the embodiment of FIG. 3 without the container;

FIG. 5 shows a detailed view of the connection between the torsion bars and the frame;

FIG. 6 shows a detailed view of the horizontal isolation damper;

FIG. 7 shows a detailed side view of the vertical isolation damper in a neutral position;

FIG. 8 shows a detailed side view of the vertical isolation damper in an extended position;

FIG. 9 shows a detailed side view of the vertical isolation damper in a compressed position;

FIG. 10 shows a detailed view of the connection between the torsion bar and the cradle of a preferred embodiment support system;

FIG. 11 shows the horizontal displacement of a horizontal isolation dampers 5 during an earthquake; and

FIG. 12 is a graph showing the results of a computer-based structural analysis showing a preferred embodiment of the support system compared to ground movement during an earthquake.

### DETAILED DESCRIPTION

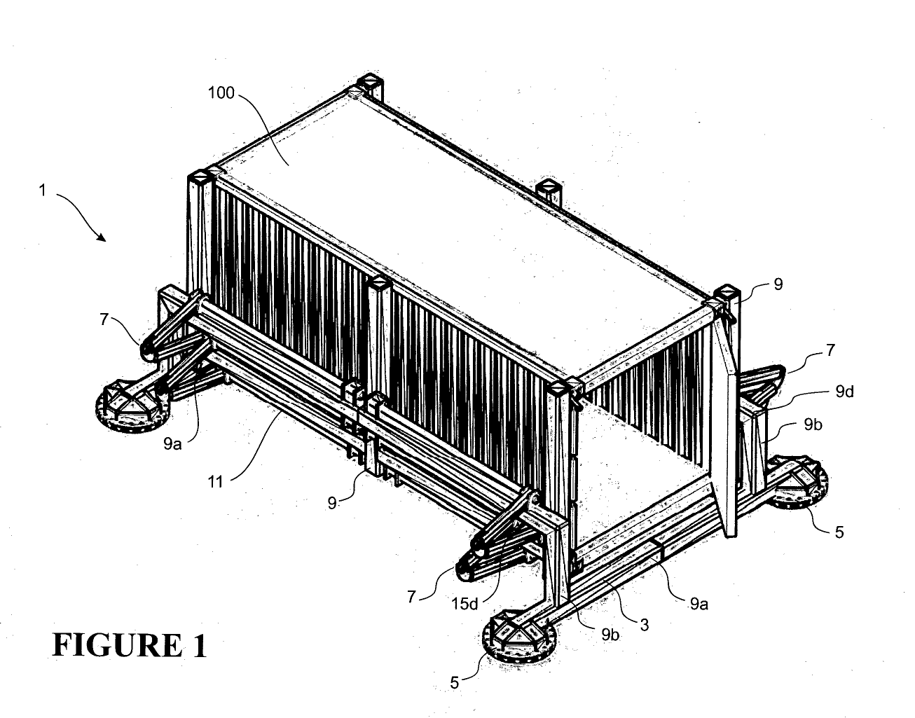

As shown in FIG. 1, a modular enclosure 100 is supported by a preferred embodiment of the support system 1. The modular enclosure shown in the accompanying drawings is a containerised data centre containing sensitive equipment, such as computers. The weight of the container and contents may be about 0.5 to about 20 tonne.

The support system 1 protects vibration-sensitive equipment stored in some form of modular enclosure 100, such as one or more shipping containers connected together, from the damaging effects of earthquake horizontal and vertical ground shaking. By using a preferred embodiment support system 1 as described herein, protection can be provided from the shaking of a maximum credible earthquake occurring in any seismic zone in the world.

The support system 1 isolates the enclosure 100 and sensitive equipment contained therein from abrupt movement of the ground or foundation, for example during an earthquake. The support system 1 has a frame or frame element 3, a horizontal isolation component in the form of one or more horizontal isolation dampers 5, and a vertical isolation component, in the form of one or more vertical isolation dampers 7.

The support system provides three dimensional isolation, where there is isolation in the vertical and horizontal directions. That is, the support system preferably isolates the modular enclosure 100 from movement in the vertical direction and movement in the horizontal direction, in terms of acceleration of the contained objects. The vertical and horizontal isolation is preferably uncoupled, that is, movement in either the vertical direction or the horizontal direction does not significantly affect movement in the other direction.

With reference to FIG. 1, the frame has a main frame 9 and a cradle 11. The main frame 9 is formed from a plurality of bars 9a that are fixed together into a generally rectangular shape, as shown. The main frame also includes legs 9b extending from the horizontal isolation dampers 5 to the bars 9a.

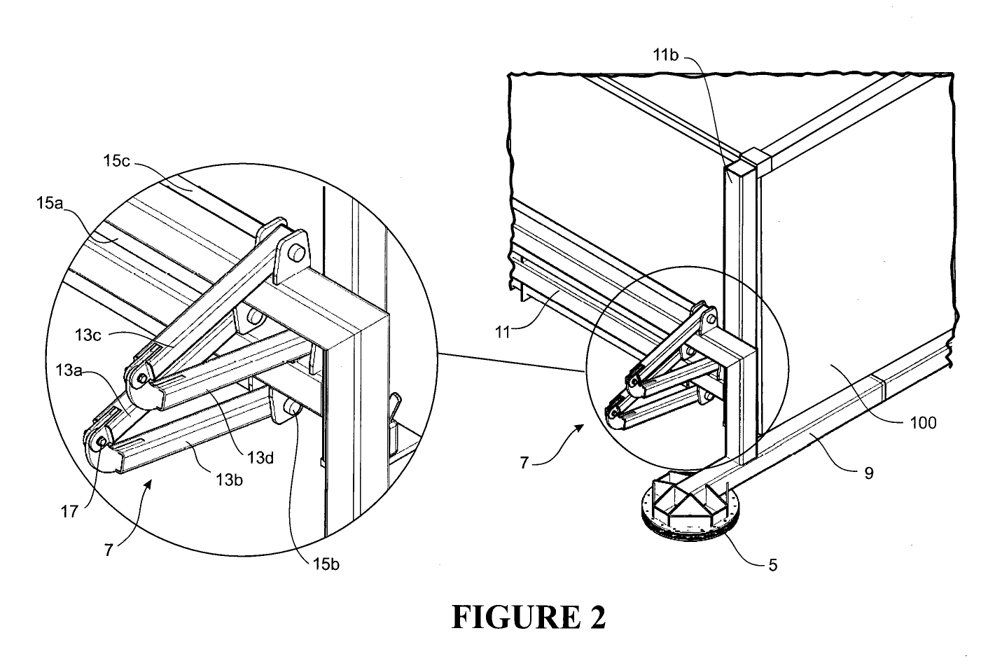

The main frame 9 sits on the horizontal isolation dampers 5, shown in detail in FIG. 2. The horizontal isolation dampers 5 provide base-isolation in horizontal direction(s). The horizontal isolation dampers are fixed to foundations or a ground surface (not shown).

One example of a suitable, commercially available horizontal isolation damper is the LoGlider damper produced by Robinson Seismic Limited of Lower Hutt, New Zealand. The LoGlider has a double acting sliding bearing which uses an elastic restoring force. The LoGlider has plates with a sliding puck sitting between the plates and the elastic restoring force is provided by elastic cords. The LoGlider is described in PCT patent application PCT/NZ2009/000043 (published as WO2009/139645), which is incorporated by reference herein. An alternative horizontal isolation damper is described in PCT patent application PCT/NZ2004/000045 (published as WO2004/079113), which is incorporated by reference herein.

The horizontal isolation dampers 5 preferably provide seismic isolation against the horizontal component of movement caused by earthquakes. Preferably, the horizontal isolation dampers 5 provide dampening of ground movement of up to at least +/−500 mm in any horizontal direction.

The cradle 11 supports the base of the modular enclosure 100. The cradle 11 is formed from a plurality of bars 11a that are fixed together into a generally rectangular shape, as shown. The cradle has vertical support bars 11b.

The support system further comprises one or more vertical isolation components 7 that enable the modular enclosure 100 to move up and down relative to the foundations or ground surface. The vertical isolation dampers 7 substantially isolate the modular enclosure from vertical ground shaking, that is, movement of the item supported by the support system is not directly related to the movement of the foundation. Rather, the item follows the movement of the foundation, but to a lesser degree and more slowly.

The/each of the vertical isolation members 7 are connected between the main frame 9 and the cradle 11, and therefore to the base of the modular enclosure. As dampening elements, these vertical isolation members dampen vibrations during an earthquake and also may help absorb movement, such as movement of people, within the modular enclosure.

A detailed view of the vertical isolation components is shown in FIG. 2. The vertical isolation damper 7 comprises suspension elements in the form of arms 13a-13d and torsion bars 15a-15d. In the preferred embodiment shown, there is a set of arms and torsion bars at or toward each corner of the frame.

In each set, there is a first pair of arms 13a, 13b and a second pair of arms 13c, 13d. The arms of the first pair 13a, 13b are pivotally connected to each other at one end by a bolt 17. The other ends of the arms are fixed to the torsion bars 15a, 15b. One of the arms 13a is fixed to the lower torsion bar 15a on the main frame 9 and the other arm 13b is fixed to the lower torsion bar 15b on the cradle. The torsion bars 15a-15d are clamped or welded to the main frame 9 or cradle 11 at one end and the arms 13a-13d at the other end. The second pair of arms 13c, 13d have a similar arrangement to the first pair of arms, except that they are fixed to the upper torsion bar 15c on the main frame 9 and fixed to the upper torsion bar 15d on the cradle 11. Each vertical isolation damper has the same arrangement of arms and torsion bars. That is, each corner of the preferred embodiment shown has four arms and four torsion bars that provide vertical damping to the modular enclosure 100.

With reference to FIGS. 1 and 2, the torsion bars are positioned above and below the frame members. In particular, the main frame lower torsion bar 15a is positioned under the main frame bar 9a, the main frame upper torsion bar 15c is positioned above the main frame bar 9a, the cradle lower torsion bar 15b is positioned under the cradle bar 11a, and the cradle upper torsion bar 15d is positioned above the cradle bar 11a.

The bars pivot independently at each support point, as seen in FIG. 2. The resistance to movement of the arm and torsion bar system increases as displacement of the cradle increases. That resistance serves to control maximum displacements in extreme events whilst allowing a softer response to smaller vibrations.

Standard earthquake design approaches consider vertical movement as 2/3 of the horizontal movement. On or very near to a fault line, this ratio can be nearer to 1 or greater. The vertical component is configured to dampen at least 300 mm of movement. The movement of at least 300 mm is +/−150 mm from a neutral position. The support system as described herein and with reference to the drawings is a system that is preferably capable of a movement +/−300 mm horizontally×+/−200 mm vertically. In a preferred embodiment the support system is capable of moving approximately 1000 mm horizontally (+/−500 mm)×600 mm (+/−300 mm) vertically. This has been found to be adequate for a critical earthquake which is calculated to require 900 mm×500 mm of compensation for vibration. Preferably, the support system will dampen movement over this maximum requirement. Preferably the support system provided will dampen up to the spectrum of 1.5 m horizontally×1 m vertically. This will preferably facilitate other potential applications for the support system, including transportation and potentially movement effected by explosion.

It should be noted that due to the interconnection, the main frame 9, cradle 11 and each of the isolation components can be varied without departing from the scope of the present invention. For example, the length of the arms 13a-13d, the length of the torsion bars 15a-15d and the diameter of the torsion bars can all be chosen or designed so that the dampening effect is optimised for a given weight of modular enclosure supported by the system. The support system 1 has vertical supports, that is, corners and other locations where there are more than four verticals.

The heights of those vertical supports are independently adjustable to allow uneven weight distribution. Those heights are adjustable by propping the container, releasing the torsion bar fixing, increasing or decreasing the torsion in the torsion bars, re-tightening the torsion bar fixings, and removing the propping.

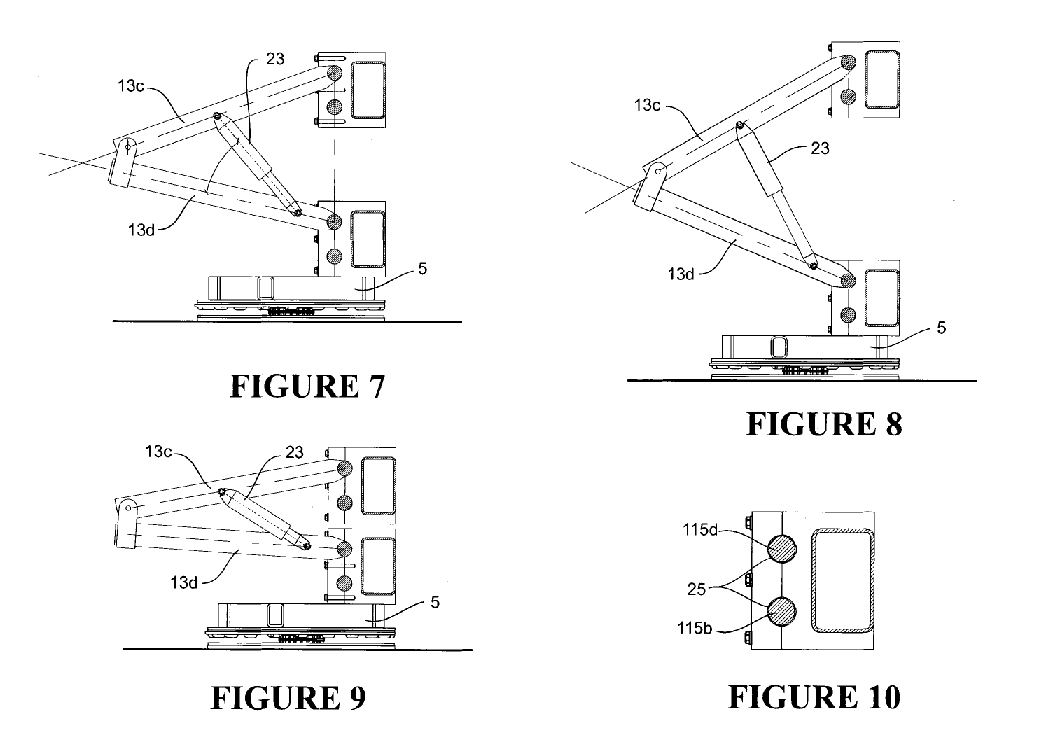

Shown is a horizontal isolation damper which may be fixed to the foundations or ground. Vertical isolation members are attached to the frame. In the preferred embodiment shown, these are formed from friction or viscous dampers connected to the suspension arms. With reference to FIGS. 7 to 9, the viscous dampers 23 may extend between a pair of bars, or between the frame and the cradle.

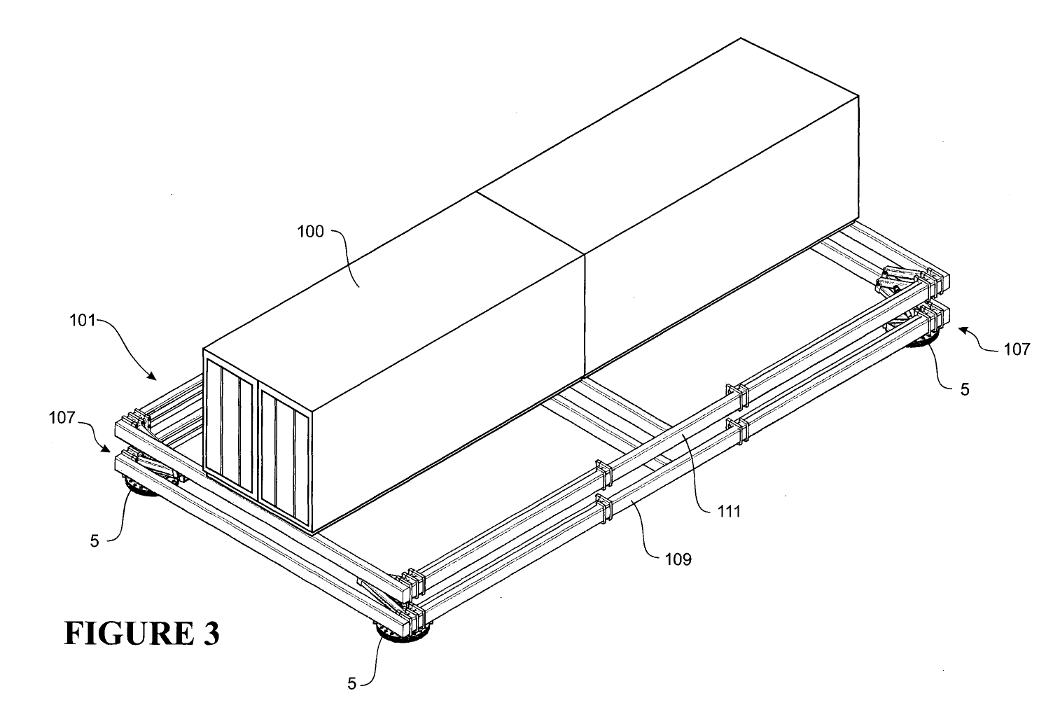

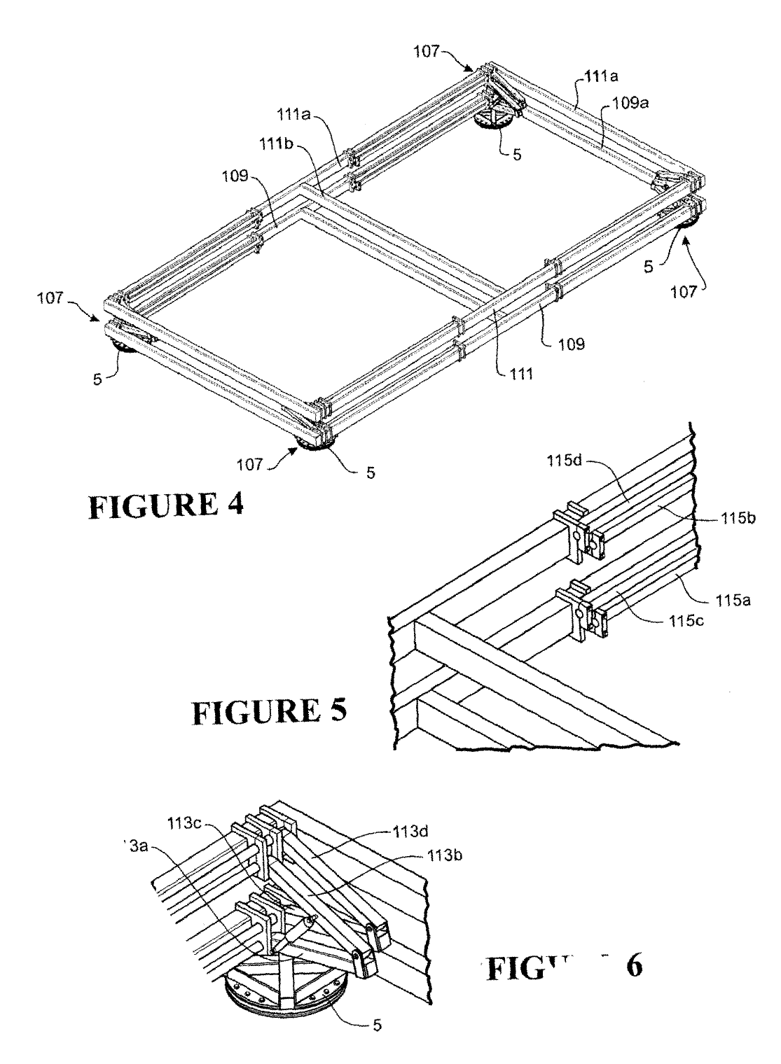

With reference to FIGS. 3 to 6, a second embodiment of the support system is shown. The components and operation of the second embodiment are similar to the first embodiment shown above, except as described below. The same reference numbers are used as above, with the addition of 100.

In the second embodiment, the main frame is in the form of a lower frame 109 and the cradle is in the form of an upper frame 111. The upper frame has additional bars 111b to provide structural support for carrying the modular enclosure 100, as required. The upper frame may have vertical supports, which are shown in FIGS. 1 and 2 of the first embodiment.

Another difference is that the arms of the vertical isolation dampers 107 extend inwardly from the upper and lower frame, rather than outwardly, as shown in FIGS. 1 and 2. Further, the torsion bars 15a-15d are positioned on an inner surface of the frame bars 111a, rather than the upper and lower surfaces of the bars as in the first embodiment.

Preferably, each of the components of the support system 1 may be made from high tensile steel for strength or aluminium alloy depending upon weight of the application. Some of the parts, especially those at the movement/bearing joints may be made from another suitable material, such as high density plastics. For example, the joint between the torsion bar and the bracket may comprises a high damping friction sleeve 25, as shown in FIG. 10.

In use, the weight of the modular enclosure 100 is supported by the cradle 11, and the cradle 11 is supported by the arms of the vertical isolation dampers 7 in the position shown in FIG. 7. The movement of each of the arms 13a-13d are controlled by the respective torsion bars 15a-15d. Because the torsion bars 15a-15d restrain movement of the arms, the load is transferred along the arms to the main frame 9. The main frame 9 holds the system rigid and transfers the loads to the horizontal isolation dampers 5 which are in turn supported by the foundation pads.

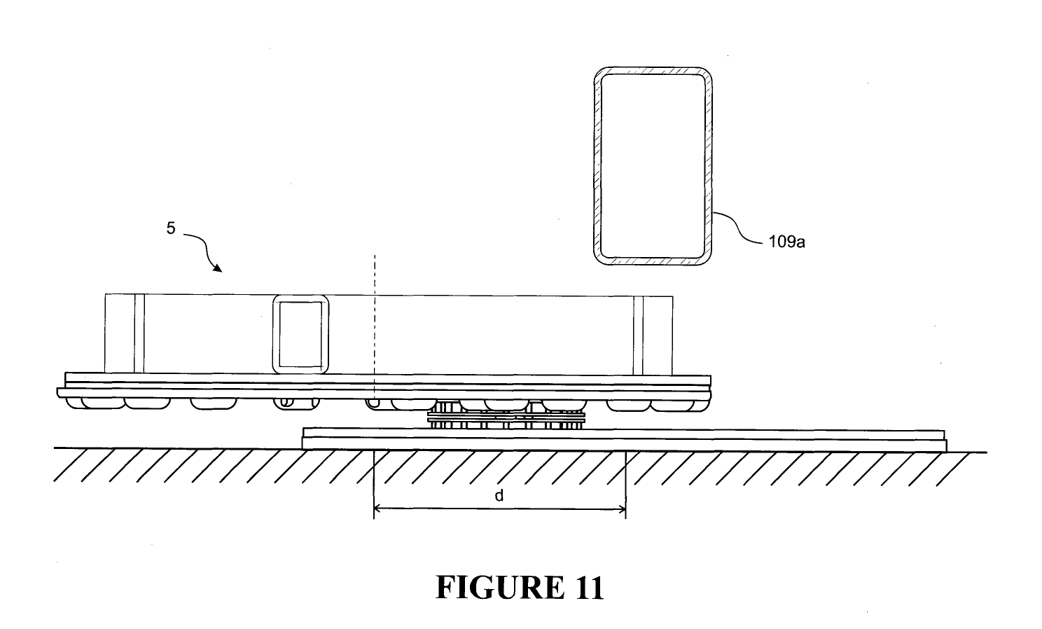

In the event of an earthquake or other abrupt movement of the foundation, the ground moves and the modular enclosure 100 follows the movement of the ground. That is, the modular enclosure 100 will oscillate in both horizontal and vertical directions. During the earthquake, the horizontal isolation dampers 5 will dampen the movement of the modular enclosure 100 in a horizontal direction. FIG. 11 shows the horizontal displacement of the horizontal isolation dampers 5 during an earthquake. The distance labelled ‘d’ is the maximum displacement of the top plate relative to the bottom plate during an abrupt movement. Simultaneously, the arms 13a-13d and torsion bars 15a-15d will dampen the movement of the modular enclosure 100 in a vertical direction. The vertical isolation dampers move between the positions shown in FIGS. 7 to 9. The neutral position is shown in FIG. 7 with the fully extended position being shown in FIG. 8 and the fully compressed position being shown in FIG. 9. FIGS. 7 to 9 show one pair of arms and the frame and cradle bars 9a, 11a. The other components are not shown for clarity. The viscous dampers of the vertical isolation dampers reduce the amplitude of the oscillations of modular enclosure 100 in the vertical direction. The movement of the modular enclosure 100 is less than the ground movement and slower than the ground movement because of the damping provided. That is, the system 1 reduces the absolute movement of the container relative to the absolute movement of the ground. After an earthquake, the torsion bars 15a-15d return the modular enclosure 100 back to a neutral position.

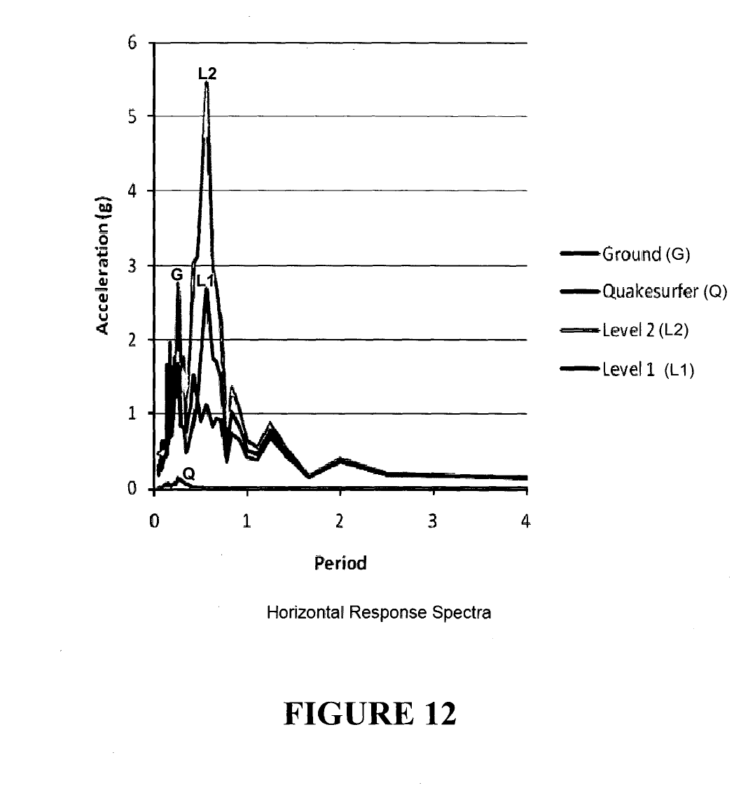

With reference to FIG. 12, an embodiment of the system was modelled as if located at Victoria University of Wellington's Kelburn Campus. Seven earthquake records, including two with ‘near fault’ effects have been scaled to the 1/500 year return period level of shaking expected, which is the design level for current modern commercial buildings.

The analysis has been carried using SAP2000, using the direct integration time-history method. SAP2000 is a structural analysis and design software. All three dimensions (horizontal and vertical) of shaking were explicitly modelled. A supported payload of 8 tonnes was assumed for this model.

To further illustrate the performance relative to the shaking experienced in a structure, a representative concrete frame building was modelled, and the accelerations compared. The concrete frame was 7.2 m×7.2 m with a 3.6 m floor to floor. Column sizes were 500×500 mm and beam sizes were 500×600 mm.

The embodiment of the support system modelled is labelled ‘Quakesurfer’ in the graph of FIG. 10. The embodiment modelled incorporates friction dampers in all three directions, and has a capacity for over +/−300 mm of horizontal travel and +/−200 mm of vertical travel. As the graph of FIG. 10 shows, the level of attenuation is significant relative to ground motions.

The isolated data centres could be used in high seismic risk areas which includes the ring of fire countries NZ, Philippines, Indonesia, Japan and western seaboard of North, Central and South America. A portable data centre supported by the preferred embodiment support system 1 could be able to protect sensitive or valuable products from maximum credible event which for a seismically active area like Wellington (or California, Manila or Tokyo) to be a magnitude 7-7.5 earthquake.

While the invention has been described with reference to preferred embodiments, it is not to be construed as being limited thereto. Moreover, where known materials and operating steps have been described, and the equivalent materials and steps are known to exist, such equivalent materials and steps are incorporated herein as if specifically set forth.

Other features of the support system 1 provided may include: that the structure can accommodate both an enclosure/container and/or open topped platform; support objects with various heights/positions of their centres of mass, and the support arms/torsion bar arrangements paired to prevent rocking or coupling between horizontal and vertical movements; a number of systems can be connected in variable configurations and scales. Adjustable parameters include: the length of arms of the vertical isolation dampers, the diameter of the torsion bars, and the length of the torsion bars.

In an embodiment shown in the accompanying drawings, the support system will be able to support a modular enclosure of 2.5×6 m or 2.5×12 m (standard shipping container sizes). Those skilled in the art will realise that the support system can be scaled up or down depending on the desired use. For each size, the horizontal isolation dampers and vertical isolation dampers will need to be adjusted, to achieve the desired dampening effect for each size and weight to be supported.

In one embodiment, the support system may be able to support an enclosure of 12×12 m.

There are other applications envisioned for the support system as described, other than that of protecting valuable equipment from the effects of earthquakes. For example, fragile equipment, artworks, or other delicate items.

The preferred embodiment has been described as having torsion bars. Alternatively, the torsion bars may be other suitable long travel springs.

1. A support system for substantially isolating an object from abrupt movement of a foundation, the support system comprising:
a horizontal isolation component configured to dampen the movement of the object in a horizontal direction; and
a vertical isolation component configured to dampen the movement of the object in a vertical direction,
wherein the vertical isolation component is configured to dampen at least +/−150 mm of movement of the object relative to the foundation in the vertical direction, and
wherein the horizontal isolation component and vertical isolation component are arranged such that dampening of movement of the object in one of the horizontal and vertical directions is uncoupled from the dampening of movement of the object in the other of the horizontal or vertical directions.

2. A support system according to claim 1, wherein the support system further comprises a frame for containing and supporting the object.

3. A support system according to claim 2, wherein the frame comprises a main frame, and a cradle for containing and supporting the object, and wherein the vertical isolation component dampens the cradle and object from movement of the main frame and foundation in a vertical direction.

4. A support system according to claim 1, comprising three or more vertical isolation components.

5. A support system according to claim 4, wherein the vertical isolation component is configured to substantially isolate the object from vertical movement of the foundation of at least +/−300 mm of movement of the foundation in the vertical direction.

6. A support system according to claim 1, wherein the vertical isolation component comprises at least one suspension element.

7. A support system according to claim 6, wherein the suspension element comprises a torsion bar.

8. A support system according to claim 7, wherein the suspension element comprises a pair of arms, the arms being pivotally connected to each other at one end of each arm and fixed to the torsion bar at the other end of each arm.

9. A support system according to claim 8, wherein the suspension element comprises a first pair of arms, a respective first pair of torsion bars, a second pair of arms, and a respective second pair of torsion bars, each of the arms of the first pair of arms being pivotally connected to each other at one end and fixed to a respective torsion bar of the first pair of torsion bars at the other end, each of the arms of the second pair of arms being pivotally connected to each other at one end and fixed to a respective torsion bar of the second pair of torsion bars at the other end, and wherein the first pair of arms, the respective first pair of torsion bars, the second pair of arms, and the respective second pair of torsion bars are arranged to dampen movement of the object in a vertical direction during abrupt movement of the foundation.

10. A support system according to claim 1, wherein the horizontal isolation component comprises a base isolation element for isolating the main frame, cradle and object from movement of the foundation in a horizontal direction.

11. A support system according to claim 1, comprising three or more horizontal isolation components.

12. A support system according to claim 1, wherein the horizontal isolation component(s) are/is fixed to the ground, floor, or other foundation element.

13. A support system according to claim 1, wherein the horizontal isolation component is configured to dampen at least +/−500 mm of movement of the foundation in a horizontal direction.

14. A support system according to claim 1, wherein the horizontal isolation component and the vertical isolation component dampen substantially the same amount of movement.

15. A support system according to claim 1, wherein the horizontal isolation component(s) and the vertical isolation component(s) dampen an equivalent amount of movement.

16. A support system according to claim 1, wherein the horizontal isolation component(s) and the vertical isolation component(s) operate independently of each other.

17. A combination of a support system as claimed in claim 1 together with an object supported by the support system.

18. A support system according to claim 17, wherein the object comprises an enclosure.

19. A support system according to claim 18, wherein the enclosure comprises a containerised data centre.

20. A support system for substantially isolating an object from abrupt movement of a foundation, the support system comprising:
a frame operatively attached to the foundation;
a cradle for supporting the object;
a horizontal isolation component, the horizontal isolation component being configured to allow movement of the frame relative to the foundation and dampen movement of the object in a horizontal direction during abrupt movement of the foundation; and
a vertical isolation component operatively connected between the frame and the cradle, the vertical isolation component being configured to allow movement of the cradle relative to the frame in a vertical direction and dampen movement of the object in a vertical direction during abrupt movement of the foundation,
wherein the frame, the cradle, the horizontal isolation component and the vertical isolation component are arranged such that movement of the cradle relative to the frame in a vertical direction is uncoupled from movement of the frame relative to the foundation in a horizontal direction.

21. A support system according to claim 20, wherein the vertical isolation component is configured to allow and dampen at least 300 mm of movement of the cradle relative to the frame in a vertical direction.

22. A support system according to claim 20, comprising three or more vertical isolation components.

23. A support system according to claim 20, wherein the vertical isolation component comprises at least one suspension element.

24. A support system according to claim 23, wherein the suspension element comprises a torsion bar.

25. A support system according to claim 24, wherein the suspension element comprises a pair of arms, the arms being pivotally connected to each other at one end of each arm and connected to the torsion bar at the other end of each arm.

26. A support system according to claim 25, wherein the suspension element comprises a first pair of arms, a respective first pair of torsion bars, a second pair of arms, and a respective second pair of torsion bars, each of the arms of the first pair of arms being pivotally connected to each other at one end and fixed to a respective torsion bar of the first pair of torsion bars at the other end, each of the arms of the second pair of arms being pivotally connected to each other at one end and fixed to a respective torsion bar of the second pair of torsion bars at the other end, and wherein the first pair of arms, the respective first pair of torsion bars, the second pair of arms, and the respective second pair of torsion bars are arranged to dampen movement of the object in a vertical direction during abrupt movement of the foundation.

27. A support system according to claim 20, wherein the horizontal isolation component comprises a base isolation element for isolating the main frame, cradle and object from movement of the foundation in a horizontal direction.

28. A support system according to claim 20, comprising three or more horizontal isolation components.

29. A support system according to claim 20, wherein the horizontal isolation component is fixed to the ground, a floor, or other foundation element.

30. A support system according to claim 20, wherein the horizontal isolation component(s) is configured to allow and dampen at least +/−500 mm of movement of the frame relative to the foundation in a horizontal direction.

31. A support system according to claim 20, wherein the horizontal isolation component and the vertical isolation component dampen substantially the same amount of movement.

32. A support system according to claim 20, wherein the horizontal isolation component and the vertical isolation component dampen an equivalent amount of movement.

33. A support system according to claim 20, wherein the horizontal isolation component and the vertical isolation component operate independently of each other.

34. A combination of a support system as claimed in claim 20 together with an object supported by the support system.

35. A support system according to claim 34, wherein the object comprises an enclosure.

36. A support system according to claim 35, wherein the enclosure comprises a containerised data centre.
